(19) United States
(12) Patent Application Publication
(10) Pub. No.: US 2023/0361240 A1
(43) Pub. Date: Nov. 9, 2023

(54) APPARATUS FOR MANUFACTURING DISPLAY DEVICE AND METHOD OF MANUFACTURING DISPLAY DEVICE

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/089,810

(22) Filed: Dec. 28, 2022

(30) Foreign Application Priority Data
May 6, 2022 (KR) 10-2022-0056199

(51) Int. Cl. H01L 33/00; H01L 33/44; H01L 25/075

(52) U.S. Cl. CPC H01L 33/0093; H01L 25/0753; H01L 33/44; H01L 2933/0025

(57) ABSTRACT

An apparatus for manufacturing a display device includes a stage on which a substrate of the display device is disposed, a mold including a surface including recessed portions, an injector that applies an ink including light emitting elements on the surface of the mold, a doctor blade that removes the ink from the surface of the mold and remains the ink disposed in the recessed portions of the mold, and a compressor that compresses the surface of the mold to the substrate.

### CROSS REFERENCE TO RELATED APPLICATION(S)

This application claims priority to and benefits of Korean Patent Application No. 10-2022-0056199 under 35 U.S.C. §119, filed on May 6, 2022, in the Korean Intellectual Property Office, the entire content of which are incorporated herein by reference.

### BACKGROUND

### 1. Technical Field

Embodiments relate to an apparatus for manufacturing a display device and a method of manufacturing the display device.

### 2. Description of the Related Art

Recently, as interest in information display is increased, research and development of a display device have been continuously conducted.

### SUMMARY

Embodiments provide an apparatus for manufacturing a display device capable of efficiently and accurately disposing light emitting elements on a substrate of the display device by using a mold, which includes recessed portions corresponding to an arrangement of the light emitting elements, and by using a doctor blade removing an ink of a surface of the mold.

Embodiments provide a method of manufacturing the display device by using the apparatus.

However, embodiments are not limited to those set forth herein. The above and other embodiments will become more apparent to one of ordinary skill in the art to which the disclosure pertains by referencing the detailed description of the disclosure given below.

In an embodiment, an apparatus for manufacturing a display device may include a stage on which a substrate of the display device is disposed, a mold including a surface including recessed portions, an injector that applies an ink including light emitting elements on the surface of the mold, a doctor blade that removes the ink applied to a portion and remains the ink disposed in the recessed portions of the mold, and a compressor that compresses the surface of the mold to the substrate.

A depth of each of the recessed portions may be greater than a diameter of each of the light emitting elements, and the depth of each of the recessed portions may be smaller than about 1.5 times of the diameter of each of the light emitting elements.

Each of the recessed portions may include an alignment hole filled with at least one of the light emitting elements.

A length of the alignment hole in a first direction may be greater than a length of each of the light emitting elements, a width of the alignment hole in a second direction intersecting the first direction may be greater than the diameter, and the width of the alignment hole in the second direction may be smaller than about 1.5 times of the diameter.

The recessed portions may be disposed in the first direction and the second direction, and the recessed portions may be disposed in a shape in which the light emitting elements are aligned on the substrate.

The doctor blade may scrape the ink in a direction on the surface of the mold, and the light emitting elements may be disposed in an alignment form of the recessed portions.

A lower surface of the alignment hole may be substantially flat.

The alignment hole may include a curved surface or an inclined surface.

Each of the recessed portions may further include a step portion or an inclined surface adjacent to the alignment hole.

The apparatus may further include a dryer that evaporates and removes a solvent of the ink remaining on the surface of the mold or on a surface of the substrate.

The apparatus may further include a vibrator that vibrates the substrate or the mold to which the ink is applied.

The vibrator may be configured to vibrate the mold by generating a sound wave or an ultrasonic wave, and at least one of the light emitting elements may be filled in each of the recessed portions by the vibrator.

In case that the mold and the substrate are separated, the vibrator may be configured to vibrate the substrate.

The apparatus may further include an electric field generator that fixes a position of each of the light emitting elements by applying an electric field to the substrate in case that the mold and the substrate are separated.

In an embodiment, a method of manufacturing a display device may include applying an ink including light emitting elements to a surface of a mold including recessed portions, removing the ink disposed on the surface of the mold and remaining the ink disposed in the recessed portions of the mold by using a doctor blade, compressing the mold to a substrate of the display device to dispose the light emitting elements on electrodes formed on the substrate, and separating the mold from which the light emitting elements are separated from the substrate.

The removing of the ink may include aligning the light emitting elements by scraping the surface of the mold by the doctor blade, and removing a solvent of the ink remaining on the surface of the mold by irradiating light to the surface of the mold.

The removing of the ink may include vibrating the mold by using a vibrator so that at least one of the light emitting elements is filled in each of the recessed portions, aligning the light emitting elements by scraping the surface of the mold by the doctor blade, and removing a solvent of the ink remaining on the surface of the mold by irradiating light to the surface of the mold.

The separating of the mold from the substrate may include fixing the light emitting elements on the electrodes by applying an electric field on the substrate by an electric field generator, and separating the mold from the substrate by moving the mold in a vertical direction.

The separating of the mold from the substrate may further include removing a solvent of the ink remaining on a surface of the substrate by irradiating light on the substrate from which the mold is separated.

The separating of the mold from the substrate may include fixing the light emitting elements on the electrodes by applying an electric field on the substrate by an electric field generator, applying a vibration to the substrate by a vibrator, and separating the mold from the substrate by moving the mold in a vertical direction.

The apparatus for manufacturing the display device and the method of manufacturing the display device according to embodiments may provide the light emitting elements disposed in advance by using the arrangement of the recessed portions of the mold on the electrodes of the substrate. Therefore, misalignment of the light emitting elements may be greatly reduced. Accordingly, a product defect may be reduced, and alignment reliability and manufacturing yield may be improved.

However, an effect of the disclosure is not limited to the above-described effect, and may be variously expanded without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic perspective view illustrating a light emitting element according to embodiments;

FIG. 2 is a schematic cross-sectional view illustrating an example of the light emitting element of FIG. 1;

FIG. 3 is a schematic plan view illustrating a display device according to embodiments;

FIG. 4 is a schematic diagram illustrating an example of a pixel included in the display device of FIG. 3;

FIG. 5 is a schematic diagram illustrating an apparatus for manufacturing a display device according to embodiments;

FIG. 6A is a schematic cross-sectional view illustrating an example of a portion of a mold included in the apparatus of FIG. 5;

FIG. 6B is a plan view illustrating an example of a portion of the mold of FIG. 6A;

FIGS. 7 to 12 are schematic cross-sectional views illustrating other examples of a portion of the mold included in the apparatus of FIG. 5;

FIG. 13 is a schematic diagram illustrating another example of the apparatus for manufacturing the display device of FIG. 5;

FIG. 14 is a schematic diagram illustrating still another example of the apparatus for manufacturing the display device of FIG. 5;

FIG. 15 is a schematic diagram illustrating still another example of the apparatus for manufacturing the display device of FIG. 5;

FIGS. 16 to 25 are schematic diagrams illustrating a method of manufacturing a display device according to embodiments;

FIG. 26 is a schematic diagram illustrating an example of a process of separating a substrate and a mold of FIG. 25;

FIG. 27 is a schematic diagram illustrating another example of a process of separating the substrate and the mold of FIG. 25; and

FIG. 28 is a schematic diagram illustrating an example of a process of removing a solvent of an ink.

### DETAILED DESCRIPTION OF THE EMBODIMENT

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z - axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

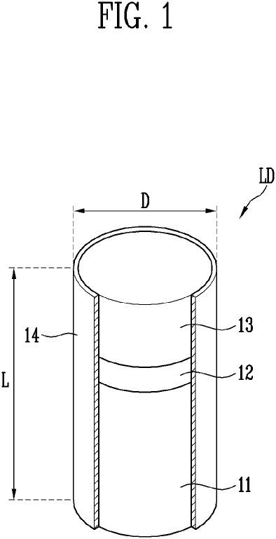

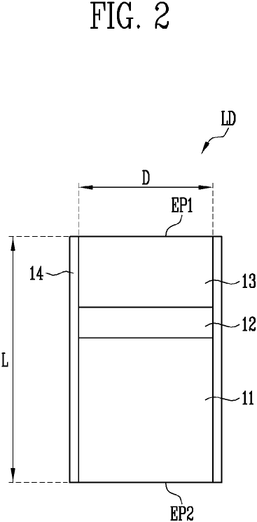

FIG. 1 is a schematic perspective view illustrating a light emitting element LD according to embodiments, and FIG. 2 is a schematic cross-sectional view illustrating an example of the light emitting element LD of FIG. 1.

In an embodiment, a type and/or a shape of the light emitting element LD are/is not limited to the embodiments shown in FIGS. 1 and 2.

Referring to FIGS. 1 and 2, the light emitting element LD may include a first semiconductor layer 11, a second semiconductor layer 13, and an active layer 12 interposed between the first semiconductor layer 11 and the second semiconductor layer 13. For example, the light emitting element LD may be implemented in a light emitting stack (or a stack pattern) in which the first semiconductor layer 11, the active layer 12, and the second semiconductor layer 13 are sequentially stacked.

The light emitting element LD may be formed in a shape extending in a direction. In case that an extension direction of the light emitting element LD is referred to as a length direction, the light emitting element LD may include a first end portion EP1 and a second end portion EP2 along the length direction. A semiconductor layer of the first semiconductor layer 11 and the second semiconductor layer 13 may be positioned at the first end portion EP1 of the light emitting element LD, and the other semiconductor layer of the first semiconductor layer 11 and the second semiconductor layer 13 may be positioned at the second end portion EP2 of the light emitting element LD. For example, the second semiconductor layer 13 may be positioned at the first end portion EP1 of the light emitting element LD, and the first semiconductor layer 11 may be disposed at the second end portion EP2 of the light emitting element LD.

The light emitting element LD may be formed in various shapes. For example, as shown in FIG. 1, the light emitting element LD may have a rod-like shape, a bar-like shape, or a column shape that is long in the length direction (or having an aspect ratio greater than 1). As another example, the light emitting element LD may have a rod-like shape, a bar-like shape, or a column shape that is short in the length direction (or having an aspect ratio of less than 1). As still another example, the light emitting element LD may have a rod-like shape, a bar-like shape, or a column shape having an aspect ratio of 1. In another example, a diameter D of the first end portion EP1 may be different from a diameter D of the second end portion EP2.

The light emitting element LD may have, for example, a diameter D and/or a length L of about a nano scale (or nano meter) to a micro scale (or micro-meters). For example, the light emitting element LD may be a light emitting diode (LED) type.

The first semiconductor layer 11 may include, for example, at least one n-type semiconductor layer. For example, the first semiconductor layer 11 may include any one semiconductor material among InAlGaN, GaN, AlGaN, InGaN, AlN, and InN, and may be an n-type semiconductor layer doped with a first conductive dopant (or an n-type dopant) such as Si, Ge, or Sn. However, the material of the first semiconductor layer 11 is not limited thereto, and other various materials may be used to form the first semiconductor layer 11.

The active layer 12 may be disposed on the first semiconductor layer 11 and may be formed in a single quantum well structure or a multiple quantum well structure. For example, in case that the active layer 12 is formed in the multiple quantum well structure, in the active layer 12, a barrier layer, a strain reinforcing layer, and a well layer may be periodically and repeatedly stacked as a single unit. The strain reinforcing layer may have a lattice constant less than that of the barrier layer to further reinforce a strain, for example, a compression strain, applied to the well layer. However, a structure of the active layer 12 is not limited to the above-described embodiment.

The active layer 12 may emit light of a wavelength of about 400 nm to about 900 nm, and may use a double hetero structure. In an embodiment, a clad layer doped with a conductive dopant may be formed on and/or under the active layer 12 along the length direction of the light emitting element LD. For example, the clad layer may be formed of an AlGaN layer, an InAlGaN layer, GaAs layer, or the like. According to an embodiment, a material of AlGaN, InAlGaN, GaAs, or the like may be used to form the active layer 12, and other various materials may be used to form the active layer 12. The active layer 12 may include a first surface contacting the first semiconductor layer 11 and a second surface contacting the second semiconductor layer 13.

In an embodiment, a color (or an output light color) of the light emitting element LD may be determined according to a wavelength of light emitted from the active layer 12. The color of the light emitting element LD may determine a color of a corresponding pixel. For example, the light emitting element LD may emit red light, green light, or blue light.

In case that an electric field of a (certain) voltage or more is applied to ends (e.g., opposite ends) of the light emitting element LD, the light emitting element LD may emit light by the combination of an electron-hole pair performed in the active layer 12. By controlling light emission of the light emitting element LD, the light emitting element LD may be used as a light source (or a light emitting source) of various light emitting devices including a pixel of the display device.

The second semiconductor layer 13 may be disposed on the second surface of the active layer 12. The first semiconductor layer 11 and the second semiconductor layer 13 may include different types of semiconductor layers. For example, the second semiconductor layer 13 may include at least one p-type semiconductor layer. For example, the second semiconductor layer 13 may include at least one semiconductor material among InAlGaN, GaN, AlGaN, InGaN, AlN, and InN, and may include a p-type semiconductor layer doped with a second conductive dopant (or a p-type dopant) such as Mg, Zn, Ca, Sr, or Ba. However, the material of the second semiconductor layer 13 is not limited thereto, and other various materials may be used to form the second semiconductor layer 13.

Although the first semiconductor layer 11 and the second semiconductor layer 13 are shown as a single layer, embodiments are not limited thereto. In an embodiment, according to the material of the active layer 12, each of the first semiconductor layer 11 and the second semiconductor layer 13 may further include at least one or more layers, for example, a clad layer and/or a tensile strain barrier reducing (TSBR) layer. The TSBR layer may be a strain relief layer disposed between semiconductor layers having different lattice structures and serving as a buffer for reducing a lattice constant difference. The TSBR layer may be formed of a p-type semiconductor layer such as p-GaInP, p-AlInP, and p-AlGaInP, but embodiments are not limited thereto.

According to an embodiment, the light emitting element LD may further include a contact electrode (hereinafter referred to as a “first contact electrode”) disposed on the second semiconductor layer 13 in addition to the above-described first semiconductor layer 11, the active layer 12, and the second semiconductor layer 13. According to an embodiment, the light emitting element LD may further include another contact electrode (hereinafter referred to as a “second contact electrode”) disposed at an end portion of the first semiconductor layer 11.

In an embodiment, the light emitting element LD may further include an insulating layer 14 (or an insulating film). In another example, the insulating layer 14 may be omitted. In another example, the insulating layer 14 may cover only a portion of the first semiconductor layer 11, the active layer 12, and the second semiconductor layer 13.

The insulating layer 14 may prevent an electrical short that may occur in case that the active layer 12 contacts a conductive material other than the first and second semiconductor layers 11 and 13.

The insulating layer 14 may include a transparent insulating material. The insulating layer 14 may be formed in a form of a single layer or may be formed in a form of multiple layers including double layers.

The above-described light emitting element LD may be used as a light emitting source (or a light source) of various display devices. The light emitting element LD may be manufactured through a surface treatment process. For example, in case that light emitting elements LD are mixed in a fluid solution (or solvent) and supplied to each pixel area (for example, an emission area of each pixel or an emission area of each sub-pixel), surface treatment may be performed on each of the light emitting elements LD so that the light emitting elements LD may be uniformly sprayed without being unevenly aggregated in the solution.

The above-described light emitting element LD may be used in various types of electronic devices that require a light source, including a display device. For example, the light emitting elements LD may be used as a light source of each pixel. However, an application field of the light emitting element LD is not limited to the above-described example. For example, the light emitting element LD may be used in other types of electronic devices that require a light source, such as a lighting device.

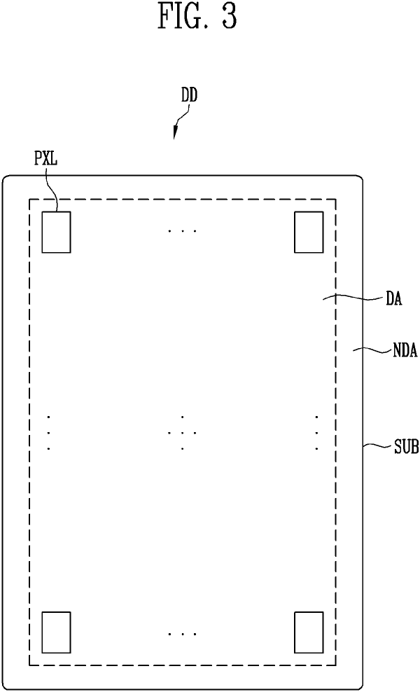

FIG. 3 is a schematic plan view illustrating a display device DD according to embodiments.

The display device DD may be applied to at least one surface of an electronic device, e.g., a smartphone, a television, a tablet PC, a video phone, an e-book reader, a desktop PC, a laptop PC, a workstation, a server, a PDA, a medical device, a camera, or a wearable device.

Referring to FIGS. 1, 2, and 3, the display device DD may include a substrate SUB, a pixel PXL formed on the substrate SUB and including at least one light emitting element LD, a driver disposed on the substrate SUB and driving the pixel PXL, and a line unit connecting the pixel PXL and the driver.

The substrate SUB may include a display area DA and a non-display area NDA.

The display area DA may be an area in which the pixel PXL displaying an image is disposed. The non-display area NDA may be an area in which the driver and a portion of the line unit connecting the pixel PXL and the driver are disposed.

The non-display area NDA may be adjacent to the display area DA. The non-display area NDA may be disposed on at least one side of the display area DA.

The line unit may provide a signal to the pixel PXL, and may include a scan line, a data line, an emission control line, and a fan-out line connected to each of the scan line, the data line, and the emission control line.

The substrate SUB may include a transparent insulating material to transmit light. The substrate SUB may be a rigid substrate or a flexible substrate.

The pixel PXL may be one of a red pixel, a green pixel, and a blue pixel. The red pixel, the green pixel, and the blue pixel may be disposed (arranged) on the display area DA in combination. However, embodiments are not limited thereto, and each of the pixels PXL may emit light in a color other than red, green, and blue. For example, the pixel PXL may emit white light.

The pixel PXL may include light emitting elements LD. The light emitting element LD may have a size as small as a nano scale (or nanometer) to a micro scale (or micrometer). The light emitting elements LD may be used to form the light source of the pixel PXL.

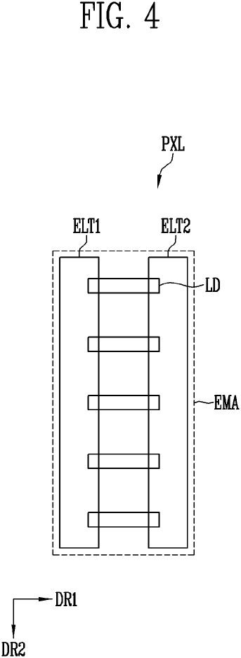

FIG. 4 is a schematic diagram illustrating an example of the pixel PXL included in the display device DD of FIG. 3.

In FIG. 4, for convenience of description, a circuit of the pixel PXL for driving the light emitting element LD is omitted. FIG. 4 schematically shows a portion of an emission area EMA of the pixel PXL.

Referring to FIGS. 1, 2, and 4, the pixel PXL may include an area defined as the emission area EMA that emits light of a (certain) color. The emission area EMA may be as an area in which the light emitting element LD is disposed to emit light of a specific wavelength band.

The pixel PXL may further include a non-emission area that is an area except for the emission area EMA. The light emitting element LD may not be disposed in the non-emission area, and the non-emission area may be an area in which light emitted from the light emitting element LD does not reach, and thus light is not emitted.

In an embodiment, the pixel PXL may include a first electrode ELT1, a second electrode ELT2, and light emitting elements LD.

The first electrode ELT1 and the second electrode ELT2 may be spaced apart from each other. The first electrode ELT1 and the second electrode ELT2 may be connected (e.g., electrically connected) to the light emitting elements LD. For example, the first electrode ELT1 may be connected (e.g., electrically connected) to the first end portion EP1 of the light emitting element LD, and the second electrode ELT2 may be connected (e.g., electrically connected) to the second end portion EP2 of the light emitting element LD.

One of the first electrode ELT1 and the second electrode ELT2 may be an anode electrode of the light emitting element LD, and the other may be a cathode electrode of the light emitting element LD. For example, different power may be connected (e.g., electrically connected) to the first electrode ELT1 and the second electrode ELT2.

In an embodiment, each of the first electrode ELT1 and the second electrode ELT2 may extend in the second direction DR2 in the emission area EMA.

The first electrode ELT1 and the second electrode ELT2 may form a single layer with a material selected from a group consisting of molybdenum (Mo), tungsten (W), aluminum neodymium (AINd), titanium (Ti), aluminum (Al), silver (Ag), and an alloy thereof alone or a in combination, or may be in a double layer or multiple layer structure of molybdenum (Mo), titanium (Ti), copper (Cu), aluminum (Al) or silver (Ag), which is a low-resistance material, in order to reduce a line resistance.

However, this is an example, and the first electrode ELT1 and the second electrode ELT2 may include at least one of various transparent conductive materials including indium tin oxide (ITO), indium zinc oxide (IZO), zinc oxide (ZnOₓ), indium gallium zinc oxide (IGZO), indium tin zinc oxide (ITZO), and the like.

The light emitting element LD may be disposed between the first electrode ELT1 and the second electrode ELT2. In an embodiment, the first end portion EP1 of the light emitting element LD may contact (e.g., directly contact) the first electrode ELT1, and the second end portion EP2 of the light emitting element LD may contact (e.g., directly contact) the second electrode ELT2. In another example, the first end portion EP1 of the light emitting element LD may be connected (e.g., electrically connected) to the first electrode ELT1 through a separate first contact electrode, and the second end portion EP2 of the light emitting element LD may be connected (e.g., electrically connected) to the second end portion EP2 of the light emitting element LD through a separate second contact electrode.

The light emitting elements LD may be spaced apart from each other. For example, the light emitting elements LD may be aligned parallel to each other in the emission area EMA. A distance at which the light emitting elements LD are spaced apart is not limited.

In an embodiment, the light emitting element LD may have a shape extending in the first direction DR1. However, this is an example, and the light emitting element LD may be disposed obliquely with respect to the first direction DR1.

The light emitting element LD may have a diameter D and/or a length of about a nano scale to a micro scale. For example, the light emitting element LD may have a rod shape, a bar shape, or a column shape that is long in the length direction.

In the conventional method of manufacturing the display device, an ink INK.

INK in which the light emitting elements LD, which are bipolar elements, are dispersed, are sprayed on a substrate on which electrodes such as the first electrode ELT1 and the second electrode ELT2 are formed, and the light emitting elements LD are aligned by applying an electric signal to the electrodes. For example, a dielectrophoretic force may be transmitted to the light emitting elements LD by an electric field generated by the electric signal applied to the electrodes, and each of the light emitting elements LD may be aligned on the first electrode ELT1 and the second electrode ELT2 in case that an orientation and a position of the light emitting elements LD are controlled.

However, during an ink ejection process, a portion of the light emitting elements LD included in the ink INK may be formed in a space where the first electrode ELT1 and the second electrode ELT2 are not disposed. For example, at least a portion of the light emitting element LD may contact a lower insulating layer (for example, a dielectric layer) exposed from the first electrode ELT1 and the second electrode ELT2.

For example, an attractive force such as a van der Waals force may be generated between the light emitting element LD and lower configurations (for example, the dielectric layer) of the first and second electrodes ELT1 and ELT contacting the light emitting element LD. In case that the attractive force affects the dielectrophoretic force, the light emitting element LD may not move or may not be aligned in an orientation of a certain position. The light emitting element LD that is not properly aligned on the first electrode ELT1 and the second electrode ELT2 may not emit light with a certain luminance, which may cause a defect of the display device DD.

Therefore, an apparatus 1000 for manufacturing a display device DD and a method of manufacturing a display device DD according to embodiments for improving alignment reliability and manufacturing yield of the light emitting elements LD are described.

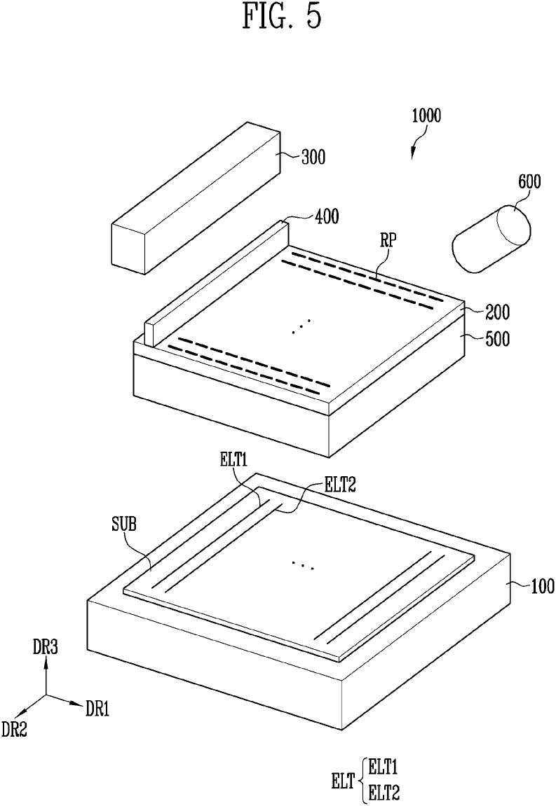

FIG. 5 is a schematic diagram illustrating an apparatus 1000 for manufacturing a display device DD according to embodiments.

In FIG. 5, a first direction DR1, a second direction DR2, and a third direction DR3 are defined. The first direction DR1 and the second direction DR2 are directions disposed on the same plane and orthogonal to each other, and the third direction DR3 is a direction perpendicular to the first direction DR1 and the second direction DR2.

In FIG. 5, each of elements of the apparatus 1000 is schematically shown for convenience of description. Each of the elements may be implemented in various shapes, positional relationships, and the like to correspond to an actual manufacturing method and operation.

Referring to FIGS. 4 and 5, the apparatus 1000 for manufacturing a display device DD may include a stage 100, a mold 200, an applying device 300 (e.g., an injector or a sprayer), a doctor blade 400, and a pressure applying device 500 (e.g., a compressor). The apparatus 1000 may further include a drying device 600 (e.g., a dryer).

The stage 100 may provide an area in which the substrate SUB of the display device DD is disposed. The substrate SUB may be disposed and fixed on the stage 100. The stage 100 may be fixed, stationary, or movable according to a process method. For example, in a process of compressing the mold 200 and the substrate SUB to each other, the stage 100 may be turned over so that an upper surface of the substrate SUB faces a bottom surface (or a lower surface).

The mold 200 may have a surface including recessed portions RP. The recessed portions RP may be formed on a surface of the mold 200 to correspond to an arrangement form of the light emitting elements LD. The mold 200 may include a material of metal, ceramic, plastic, or the like.

In an embodiment, at least one light emitting element LD may be filled in each of the recessed portions RP. The recessed portions RP may be arranged in the first direction DR1 and the second direction DR2. For example, the recessed portions RP may be arranged in a form in which the light emitting elements LD are aligned on the substrate SUB. In other words, the recessed portions RP may determine a form in which the light emitting elements LD are aligned on the substrate SUB.

Each of the recessed portions RP may be filled with at least one light emitting element LD.

The applying device 300 may apply, spray, or inject the ink INK in which the light emitting elements LD are dispersed on the surface of the mold 200. The applying device 300 may be spaced apart from the mold 200 by a (certain) distance.

In an embodiment, the applying device 300 may move in the first direction DR1 and/or the second direction DR2 to spray the ink INK on the mold 200. However, this is an example, and the applying device 300 may spray the ink INK in a fixed state, the mold 200 may move, and thus the ink INK may be applied to the surface of the mold 200.

The ink INK may include a solvent SOL and the light emitting elements LD included in the solvent SOL. For example, the ink INK may further include a dispersing agent for evenly dispersing the light emitting elements LD in the solvent SOL. The solvent included in the ink INK may be in a liquid or colloid state.

The solvent SOL may include acetone, water, alcohol, toluene, propylene glycol (PG), propylene glycol methyl acetate (PGMA), or the like. However, this is an example, and the solvent SOL may include at least one of propylene glycol methyl ether (PGME), dipropylene glycol methyl ether (DGME), tripropylene glycol methyl ether (TGME), propylene glycol methyl ether acetate (PGMEA), dipropylene glycol methyl ether acetate (DGMEA), propylen glycol n-propyl ether (PGPE), dipropylen glycol n-propyl ether (DGPE), propylen glycol n-butyl ether (PGBE), dipropylen glycol n-butyl ether (DGBE), tripropylen glycol n-butyl ether (TGBE), propylen glycol phenyl ether (PGPE), propylene glycol diacetate (PGD), dipropylen glycol dimethyl ether (DGDE), diethylene glycol ethyl ether (DGEE), diethylne glycol methyl ether (DGME), diethylne glycol n-butyl ether (DGBE), diethylne glycol hexyl ether (DGHE), diethylne glycol n-butyl ether acetate (DGBEA), ethylene glycol propyl ether (EGPE), ethylene glycol n-butyl ether (EGBE), ethylene glycol hexyl ether (EGHE), ethylene glycol n-butyle ether acetate (EGBEA), triethylene glycol methyl ether (TGME), triethylene glycol ethyl ether (TGEE), triethylene glycol n-butyl ether (TGBE), ethylene glycol phenyl ether (EGPE), and ethylene glycol n-butyle ether mixture (EGBEM).

In an embodiment, the applying device 300 may be implemented as an inkjet printing module, a dispensing module, a slit coating module, or the like. For example, the applying device 300 may apply, spray, or inject the ink INK on the mold 200 by using a print head. However, this is an example, and the applying device 300 is not limited thereto. For example, the applying device 300 may be replaced with an immersion device for immersing the surface of the mold 200 in the ink.

The doctor blade 400 may remove the ink INK applied to a portion of the mold 200 excluding the recessed portions RP. The doctor blade 400 may have a metal or resin thin plate shape.

The doctor blade 400 may contact the surface of the mold 200 and move in a direction at a (certain) contact pressure. The doctor blade 400 may push the ink INK including the light emitting element LD into the recessed portions RP and scrape the ink INK of a portion except for the recessed portion RP simultaneously. For example, the doctor blade 400 may remove the ink INK disposed on the surface of the mold 200, and may remain the ink disposed in the recessed portions RP. A series of processes by using the doctor blade 400 may include a doctor blade process.

In an embodiment, a length of the doctor blade 400 in the second direction DR2 may correspond to a length of the mold 200 in the second direction DR2. For example, the doctor blade 400 may contact the surface of the mold 200 and move in the first direction DR1 or a direction opposite to the first direction DR1. For example, the contact pressure between the doctor blade 400 and the mold 200 may be determined (controlled) so that the doctor blade 400 contacts only the surface excluding the recessed portion RP of the mold 200.

However, this is an example, and a material, a shape, a movement direction, a contact pressure, an angle, and the like of the doctor blade 400 may be determined according to a condition of a characteristic, viscosity, a material of the mold 200, and the like.

The pressure applying device 500 may compress the surface (for example, an upper surface including the recessed portions RP) of the mold 200 on the substrate SUB. The pressure applying device 500 may be positioned on a rear surface of the mold 200, and may press the mold 200 in a state in which the mold 200 and the substrate SUB are in contact with each other. Thus, the ink INK in the recessed portions RP and the light emitting elements LD included therein may be dropped (or sprayed) onto the substrate SUB.

The drying device 600 may evaporate and remove the solvent SOL of the ink INK remaining on the surface of the mold 200 or the solvent SOL of the ink INK remaining on the substrate SUB. In an embodiment, the drying device 600 may include a light source for evaporating the solvent SOL. For example, the light source may be an infrared lamp or an infrared irradiation device. However, this is an example, and the light source may be a lamp or a light irradiation device irradiating visible light or ultraviolet light.

In an embodiment, in case that the solvent SOL included in the ink INK on the mold 200 is removed, the light emitting element LD filled in the recessed portions RP may be exposed. In another example, in case that the solvent SOL included in the ink INK on the substrate SUB is removed, the light emitting element LD on the first and second electrodes ELT1 and ELT2 may be exposed.

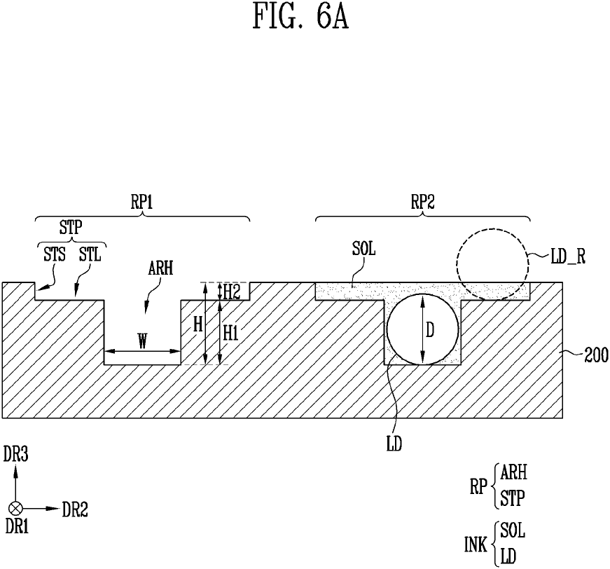

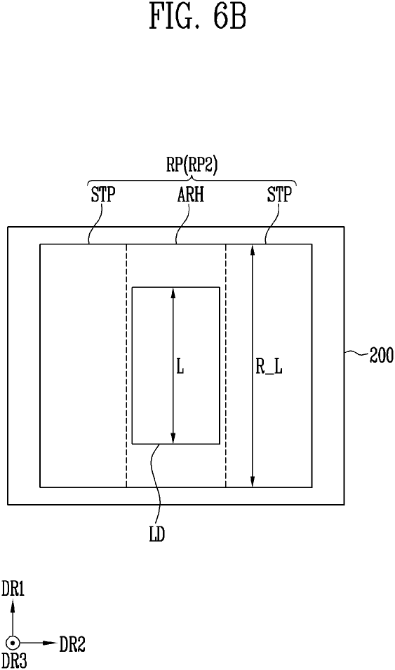

FIG. 6A is a schematic cross-sectional view illustrating an example of a portion of the mold 200 included in the apparatus 1000 of FIG. 5, and FIG. 6B is a schematic plan view illustrating an example of a portion of the mold 200 of FIG. 6A.

Referring to FIGS. 4, 5, 6A, and 6B, the surface of the mold 200 may include the recessed portion RP.

The recessed portion RP may determine a position where the light emitting element LD is disposed/arranged on the substrate SUB. For example, the light emitting element LD may be disposed on the substrate SUB to correspond to (or to overlap) a position of the recessed portion RP. A width W, a length R_L, and a depth H of the recessed portion RP may be determined based on a size of the light emitting element LD. For example, the recessed portion RP may be designed (or formed) to have a space in which the light emitting element LD may be disposed in a lying state therein.

For convenience of description, FIG. 6A shows a first recessed portion RP1 that is not filled with an ink INK and a second recessed portion RP2 filled with an ink INK including the light emitting element LD and a solvent SOL. Shapes of the first recessed portion RP1 and the second recessed portion RP2 may be substantially the same. Unless otherwise specified, it may be understood that a description of the recessed portion RP is identically applied to the first recessed portion RP1 and the second recessed portion RP2.

In an embodiment, the depth H of the recessed portion RP may be greater than the diameter D of the light emitting element LD. Therefore, the light emitting element LD lying and disposed in the recessed portion RP does not protrude from the recessed portion RP. In case that a portion of the light emitting element LD protrudes from the recessed portion RP, excessive friction or impact may be applied to the light emitting element LD in the doctor blade process, and thus damage and/or a defect of the corresponding light emitting element LD may occur.

Since the diameter D of the light emitting element LD may not be uniform, the depth H of the recessed portion RP may be determined based on a maximum diameter D of the light emitting element LD which is actually used. For example, the diameter D of the light emitting element LD may be as the light emitting element LD or the maximum diameter D of the light emitting element LD.

In an embodiment, the depth H of the recessed portion RP may be less than about 1.5 times of the diameter D of the light emitting element LD. In case that the depth H of the recessed portion RP is equal to or greater than about 1.5 times of the diameter D of the light emitting element LD, light emitting elements LD may be unintentionally stacked in the recessed portion RP. In order to prevent the light emitting elements LD from being stacked, the depth H of the recessed portion RP may be less than about 1.5 times of the diameter D of the light emitting element LD.

In an embodiment, the recessed portion RP may include an alignment hole ARH and a step portion STP including a step side surface STS and a step lower surface STL. The step portion STP may be distinguished (or defined) from the alignment hole ARH by the height difference between the alignment hole ARH and the step portion STP. The alignment hole ARH may be a portion in which the light emitting element LD is actually filled or disposed.

In an embodiment, as shown in FIG. 6B, a length R_L of the alignment hole ARH in the first direction DR1 may be longer than the length L of the light emitting element LD. For example, since the lengths of the light emitting elements LD may not be uniform, the length L of the light emitting element LD may be as a maximum length among the lengths of the actual light emitting elements LD.

In case that the length R_L of the alignment hole ARH is less than twice of the length L of the light emitting element LD, as shown in FIG. 6A, only one (single) light emitting element LD may be filled in the alignment hole ARH. In case that the length R_L of the alignment hole ARH is greater than twice of the maximum length L1 of the light emitting elements LD, two or more light emitting elements LD may be arranged in the first direction DR1 in the alignment hole ARH.

In an embodiment, as shown in FIG. 6A, the width W of the alignment hole ARH in the second direction DR2 may be greater than the diameter D of the light emitting element LD, and may be less than about 1.5 times of the diameter D of the light emitting element LD. Therefore, only one light emitting element LD may be disposed in the alignment hole ARH with respect to the second direction DR2.

In an embodiment, a depth H1 of the alignment hole ARH may be greater than a radius (for example, D/2) of the light emitting element LD and may be less than or equal to the diameter D of the light emitting element LD. Therefore, the light emitting element LD properly filled (or disposed) in the alignment hole ARH may not depart (or move out) from the alignment hole ARH in the doctor blade process.

In an embodiment, a bottom surface (or a lower surface) of the alignment hole ARH may be flat. For example, as shown in FIG. 6A, a cross-section of the alignment hole ARH may have a quadrangular shape. However, this is an example, and a cross-sectional shape of the alignment hole ARH is not limited thereto. The cross-sectional shape of the alignment hole ARH may be variously designed (or formed) according to a shape or the like of the light emitting element LD.

The step portion STP of the recessed portion RP may assist the alignment of the light emitting element LD in the recessed portion RP. For example, a depth H2 of the step portion STP (or a height of the step side surface STS) may be less than the radius of the light emitting element LD. Accordingly, in case that the light emitting element LD is supplied on the step portion STP, removal of the corresponding light emitting element LD by the doctor blade 400 may be improved.

For example, as shown in FIG. 6A, a light emitting element LD_R initially supplied by the applying device 300 may be disposed on the step portion STP (e.g., the step lower surface STL) of the second recessed portion RP2.

At this time, the doctor blade 400 may move with contacting only the surface of the mold 200 excluding the recessed portion RP including the first and second recessed portions RP1 and RP2. In case that the doctor blade 400 moves in the second direction DR2 with contacting the mold 200, the supplied light emitting element LD_R may come out from the step portion STP and may be removed from the second recessed portion RP2. As described above, since the depth H2 of the step portion STP is less than the radius of the light emitting element LD, the supplied light emitting element LD_R disposed on the step portion STP (e.g., the step lower surface STL) by the movement of the doctor blade 400 may be readily removed from the step portion STP (e.g., the step lower surface STL).

For example, the doctor blade 400 may move in a direction opposite to the second direction DR2 with contacting the mold 200. In case that the light emitting element LD is not disposed in the alignment hole ARH of the second recessed portion RP2, the supplied light emitting element LD_R may be fallen (or moved) into the alignment hole ARH by the movement of the doctor blade 400 and may fill the alignment hole ARH of the second recessed portion RP2. In case that the light emitting element LD is disposed in the alignment hole ARH of the second recessed portion RP2, the supplied light emitting element LD_R may move from the second recessed portion RP2 and move to the first recessed portion RP1. Since the ink INK has a solution or colloid state, friction/collision between light emitting elements LD_R supplied in the doctor blade process, impact on the supplied light emitting element LD_R due to friction between the mold 200 and the supplied light emitting element LD_R, damage due to the impact, and/or the like may be prevented, alleviated, or minimized.

As described above, the light emitting elements LD may be aligned on the mold 200 according to the recessed portions RP that are periodically or non-periodically arranged in the mold 200.

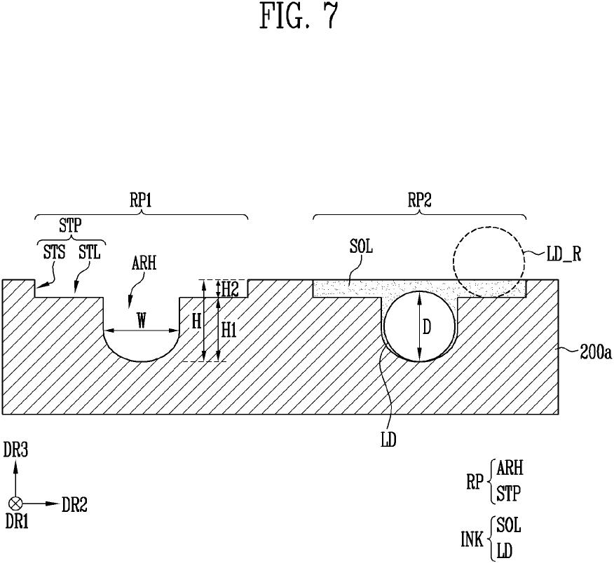

FIGS. 7 to 12 are schematic cross-sectional views illustrating other examples of a portion of the mold 200 included in the apparatus 1000 of FIG. 5.

In FIGS. 7 to 12, the same or similar components described with reference to FIGS. 6A and 6B use the same reference numerals, and a redundant description is omitted for descriptive convenience. The molds 200a, 200b, 200c, 200d, 200e, and 200f of FIGS. 7 to 12 may be substantially identical or similar to the recessed portion RP of FIGS. 6A and 6B except for a cross-sectional shape of the recessed portion RP.

Referring to FIGS. 4, 5, and 7 to 12, each of the molds 200a, 200b, 200c, 200d, 200e, and 200f may include the recessed portions RP. The recessed portion RP may be deformed or modified into various cross-sectional shapes.

In an embodiment, the depth H of the recessed portion RP may be greater than the diameter D of the light emitting element LD and less than about 1.5 times of the diameter D of the light emitting element LD.

In an embodiment, as shown in FIG. 7, the recessed portion RP may include the alignment hole ARH that may be filled with at least one light emitting element LD and the step portion STP that is separated from (or adjacent to) the alignment hole ARH.

The step portion STP (e.g., the step side surface STS and the step lower surface STL) of the recessed portion RP may assist the alignment of the light emitting element LD in the recessed portion RP. For example, the depth H2 of the step portion STP may be less than the radius of the light emitting element LD. Accordingly, in case that the light emitting element LD is supplied on the step portion STP (e.g., the step lower surface STL), removal of the corresponding light emitting element LD by the doctor blade 400 may be improved.

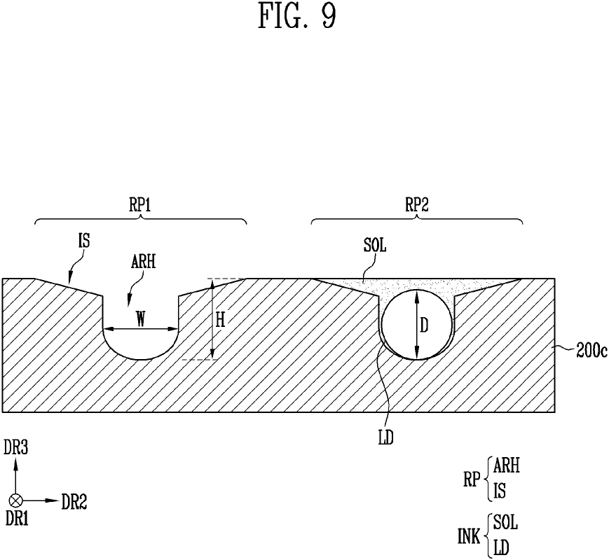

The light emitting element LD may be disposed in a substantially lying state in the alignment hole ARH. In an embodiment, as shown in FIGS. 7 and 9, a bottom surface (or a lower surface) of the alignment hole ARH of the molds 200a and 200c may include a curved surface. The curved surface of the bottom surface (or a lower surface) may be similar to a portion of an outer circumferential surface of the light emitting element LD. Accordingly, fluidity of the light emitting element LD in the alignment hole ARH may be reduced.

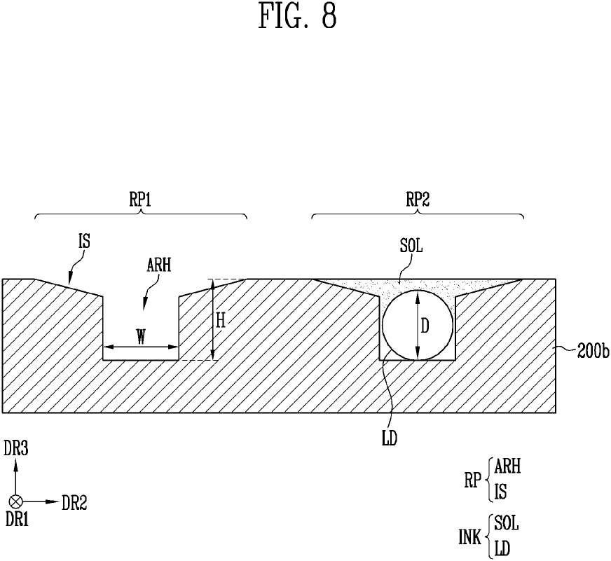

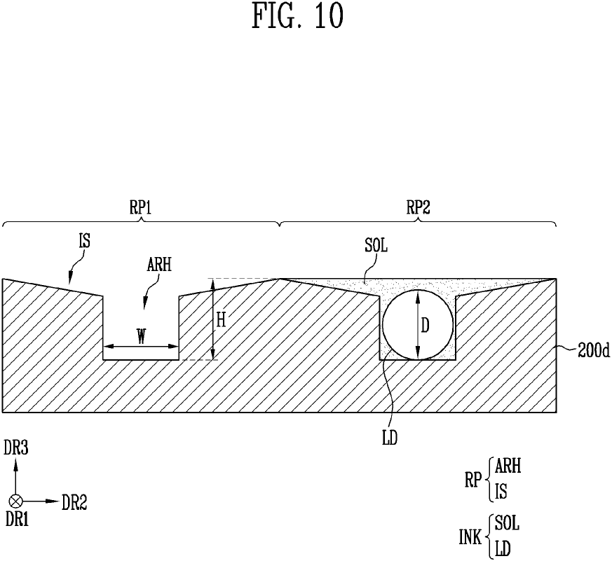

In an embodiment, as shown in FIGS. 8, 9, and 10, the recessed portion RP of the molds 200b, 200c, and 200d may include the alignment hole ARH and an inclined surface IS separated from the alignment hole ARH. The bottom surface (or a lower surface) of the alignment hole ARH may be flat (shown in FIGS. 8 and 10) or may have a curved surface (shown in FIG. 9).

The inclined surface IS may facilitate (or guide) movement of the light emitting element LD into the alignment hole ARH and the removal of the light emitting element LD. For example, in an ink application process including the light emitting element LD, the light emitting element LD supplied on the inclined surface IS may be readily moved into the alignment hole ARH by the inclined surface IS. For example, the movement of the light emitting element LD may be improved through the inclined surface IS in the doctor blade process.

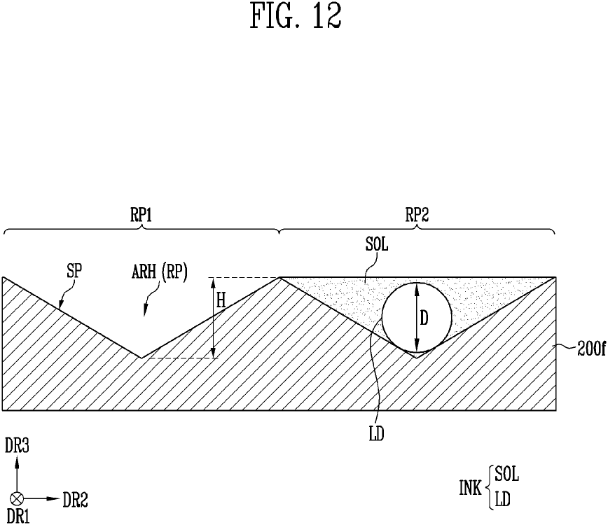

In an embodiment, as shown in FIGS. 7, 8, 9, and 11, the first recessed portion RP1 and the second recessed portion RP2 of the molds 200a, 200b, 200c, and 200e may be separated (or spaced apart) from each other. In another example, as shown in FIGS. 10 and 12, the first recessed portion RP1 and the second recessed portion RP2 may be successively formed in the second direction DR2. A distance, a size, and the like between the first and second recessed portions RP1 and RP2 may be determined to correspond to an alignment shape or the like of the light emitting elements LD.

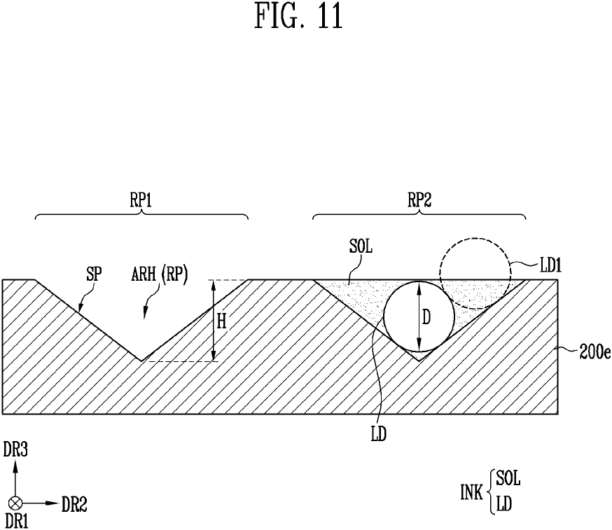

In an embodiment, as shown in FIGS. 11 and 12, the recessed portion RP may include an alignment hole ARH having a slope surface SP. The depth H of the alignment hole ARH may be substantially the same as the depth H of the recessed portion RP. In case that viewed in the first direction DR1, only one light emitting element LD may be filled in the recessed portion RP. The light emitting element LD supplied to the second recessed portion RP2, which is to be removed, may be moved to an outside of the second recessed portion RP2 by the doctor blade process.

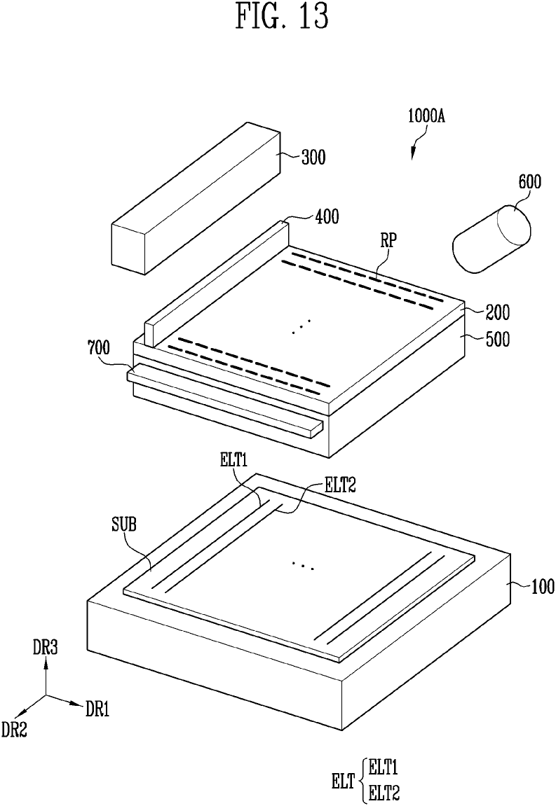

FIG. 13 is a schematic diagram illustrating another example of the apparatus 1000A for manufacturing the display device DD of FIG. 5.

In FIG. 13, the same or similar components described with reference to FIG. 5 use the same reference numerals, and a redundant description is omitted for descriptive convenience. The apparatus 1000A for manufacturing the display device DD of FIG. 13 may be substantially identical or similar to the apparatus 1000 for manufacturing the display device DD of FIG. 5, except for a first vibrator in the form of a first vibrating device 700.

Referring to FIGS. 4 and 13, the apparatus 1000A for manufacturing the display device DD may include the stage 100, the mold 200, the applying device 300, the doctor blade 400, the pressure applying device 500, the drying device 600, and the first vibrating device 700.

In an embodiment, the first vibrating device 700 may vibrate the mold 200 to which the ink INK is applied. The first vibrating device 700 may be connected to the pressure applying device 500 connected to the mold 200. The first vibrating device 700 may vibrate the mold 200 through the pressure applying device 500. In another example, the first vibrating device 700 may be connected (e.g., directly connected) to the mold 200 to vibrate the mold 200.

In an embodiment, the first vibrating device 700 may generate a sound wave or an ultrasonic wave to vibrate the mold 200. For example, the first vibrating device 700 may include a sound wave vibrator or an ultrasonic vibrator. The position and/or orientation of the light emitting elements LD included in the ink INK disposed on the mold 200 may be changed by a vibration of the mold 200. Accordingly, at least one of the light emitting elements LD may be filled or disposed in each recessed portion RP.

However, this is an example, and the first vibrating device 700 is not limited thereto. For example, the first vibrating device 700 itself may vibrate minutely at a (certain) frequency, and thus the pressure applying device 500 and/or the mold 200 contacting the first vibrating device 700 may vibrate minutely.

Accordingly, most of the light emitting elements LD may be aligned in advance before the doctor blade process, and alignment accuracy may be improved.

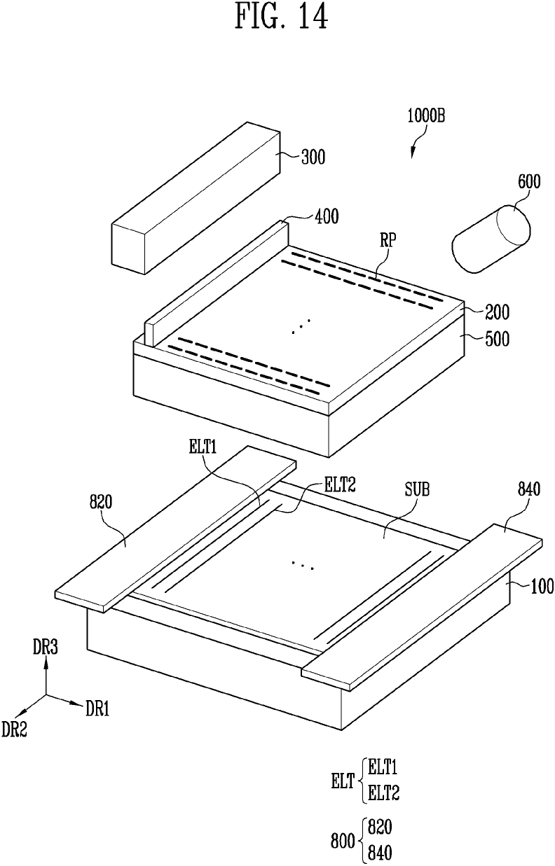

FIG. 14 is a schematic diagram illustrating still another example of the apparatus 1000B for manufacturing the display device DD of FIG. 5.

In FIG. 14, the same or similar components described with reference to FIG. 5 use the same reference numerals, and a redundant description is omitted for descriptive convenience. The apparatus 1000B for manufacturing the display device DD of FIG. 14 may be substantially identical or similar to the apparatus 1000 for manufacturing the display device DD of FIG. 5, except for an electric field generator in the form of an electric field applying device 800.

Referring to FIGS. 4 and 14, the apparatus 1000B for manufacturing the display device DD may include the stage 100, the mold 200, the applying device 300, the doctor blade 400, the pressure applying device 500, the drying device 600, and the electric field applying device 800.

In an embodiment, the electric field applying device 800 may apply an electric field on the substrate SUB to fix the position of the light emitting elements LD. For example, the electric field applying device 800 may include a first probe unit 820 connected (e.g., electrically and physically connected) to a side of the substrate SUB, and a second probe unit 840 connected (e.g., electrically and physically connected) to another side opposite to the side of the substrate SUB.

The first probe unit 820 and the second probe unit 840 may include probe pads transmitting an electrical signal. The probe pads of the first probe unit 820 may be connected (e.g., electrically connected) to pads or electrodes disposed on the side of the substrate SUB, and the probe pads of the second probe unit 840 may be connected (e.g., electrically connected) to pads or electrodes of the other side of the substrate SUB. In FIG. 14, the first and second probe units 820 and 840 are schematically shown in a plate shape in which the first and second probe units 820 and 840 are disposed on sides (e.g., opposite sides) of the substrate SUB, respectively, but this is an example, and a shape and a disposition of the first and second probe units 820 and 840 are not limited thereto.

The electric field applying device 800 may provide an electric signal to the first and second probe units 820 and 840, and the probe pads may form an electric field on the substrate SUB through the electric signal. This electrical signal may be an alternating voltage.

The light emitting elements LD may receive a dielectrophoretic force by the electric field, and the position/orientation of each of the light emitting elements LD may be fixed according to a magnitude and a direction of the dielectrophoretic force in case that the electric field is applied.

An electric field application driving of the electric field applying device 800 may be performed during a process of separating the mold 200 and the substrate SUB. In an embodiment, before the mold 200 and the substrate SUB are separated, the electric field applying device 800 may be driven. Therefore, misalignment and separation due to movement/rotation or the like of the light emitting elements LD may be prevented, and the mold 200 and the substrate SUB may be separated in a state in which the electric field is applied to the substrate SUB.

Therefore, separation, misalignment, and the like of the light emitting element LD that may occur during a process in which the mold 200 is separated from the substrate SUB may be prevented or reduced.

In an embodiment, the apparatus 1000B for manufacturing the display device DD may further include the first vibrating device 700 described with reference to FIG. 13.

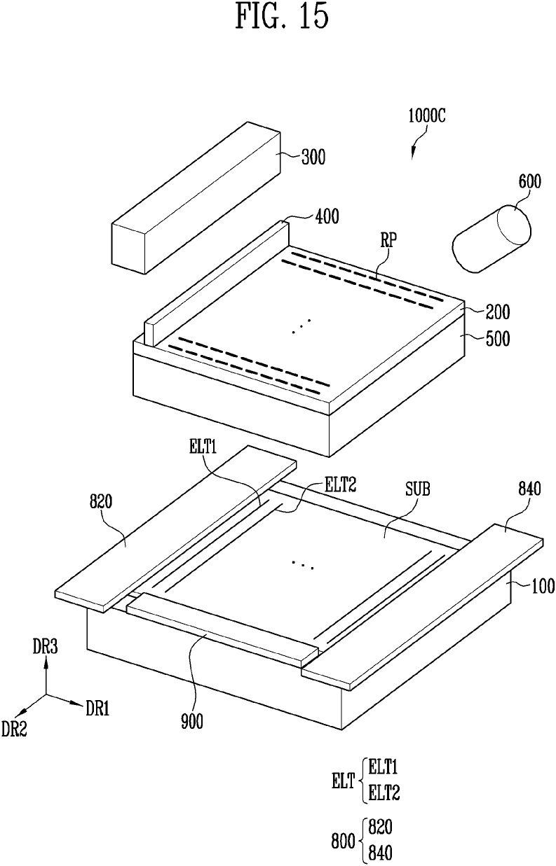

FIG. 15 is a schematic diagram illustrating still another example of the apparatus 1000C for manufacturing the display device DD of FIG. 5.

In FIG. 15, the same or similar components described with reference to FIGS. 5 and 14 use the same reference numerals, and a redundant description is omitted for descriptive convenience. The apparatus 1000C for manufacturing the display device DD of FIG. 15 may be substantially identical or similar to the apparatus 1000B for manufacturing the display device DD of FIG. 14, except for a second vibrator in the form of a second vibrating device 900.

Referring to FIGS. 5 and 15, the apparatus 1000C for manufacturing the display device DD may include the stage 100, the mold 200, the applying device 300, the doctor blade 400, the pressure applying device 500, the drying device 600, the electric field applying device 800, and the second vibrating device 900.

In an embodiment, the second vibrating device 900 may vibrate the substrate SUB. The second vibrating device 900 may be connected to the substrate SUB and/or the stage 100 supporting the substrate SUB.

In an embodiment, the second vibrating device 900 may generate a sound wave or an ultrasonic wave to vibrate the substrate SUB. For example, the second vibrating device 900 may include a sound wave vibrator or an ultrasonic vibrator.

In case that the mold 200 and the substrate SUB are separated, the second vibrating device 900 may vibrate the substrate SUB. For example, the second vibrating device 900 may assist the separation process of the mold 200 and the substrate SUB. For example, separation of the mold 200 and the substrate SUB and separation of the mold 200 and the ink INK (for example, the solvent SOL of the ink INK) may be improved by vibration by the second vibrating device 900. At this time, force transmitted to the light emitting element LD by the vibration may be less than the dielectrophoretic force due to the electric field. Therefore, the mold 200 and the substrate SUB may be readily separated without a change of the position and orientation of the light emitting element LD due to vibration of the substrate SUB.

In an embodiment, the apparatus 1000C for manufacturing the display device DD may further include the first vibrating device 700 described with reference to FIG. 13.

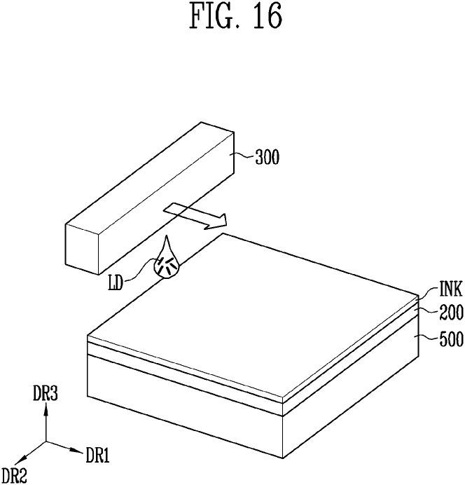

FIGS. 16 to 25 are schematic diagrams illustrating a method of manufacturing a display device DD according to embodiments.

Referring to FIGS. 16 to 25, the method of manufacturing the display device DD may include applying the ink INK in which light emitting elements LD are dispersed to the surface of the mold 200 including the recessed portions RP, removing the ink INK applied to a portion except for the recessed portions RP of the mold 200 by using the doctor blade 400, compressing the mold 200 to the substrate SUB of the display device DD to provide the light emitting elements LD on the electrodes ELT1 and ELT2 formed on the substrate, and separating the mold 200 from which the light emitting elements LD are separated from the substrate SUB.

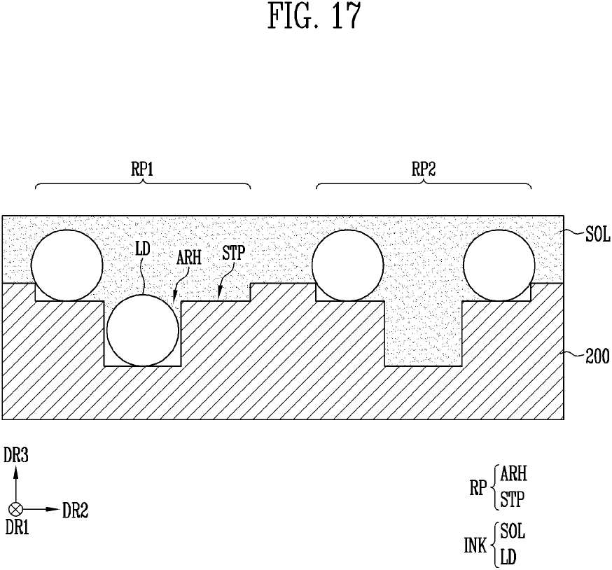

First, as shown in FIGS. 16 and 17, the ink INK may be applied to the surface of the mold 200 by using the applying device 300. In an embodiment, the applying device 300 may spray or apply the ink INK to the surface of the mold 200 with moving in the first direction DR1. However, this is an example, and a movement direction of the applying device 300 is not limited thereto. For example, a movement of the applying device 300 may be fixed, and the ink INK may be applied on the mold 200 in case that the mold 200 is moved in a (certain) direction.

The ink INK may be applied on the mold 200 by various process methods such as an inkjet printing method, a dispensing method, a coating method such as slit coating, or an immersion method.

As shown in FIG. 17, the ink INK may include the fluid solution (e.g., solvent SOL) and the light emitting elements LD dispersed in the solvent SOL. The solvent SOL may be in a liquid or colloid state. The solvent SOL may be evenly applied on the surface of the mold 200 including the first recessed portion RP1 and the second recessed portion RP2. The light emitting elements LD may be randomly disposed on the surface of the mold 200.

For example, a portion of the light emitting elements LD may be disposed in the alignment hole ARH, and another portion of the light emitting elements LD may be disposed on the step portion STP (e.g., the step side surface STS and the step lower surface STL) of the recessed portion RP. For example, still another portion of the light emitting elements LD may be disposed on the surface of the mold 200 other than the recessed portion RP, and a form in which the light emitting elements LD are disposed may also be different.

For example, a cross-sectional shape of the mold 200 of FIG. 17 is an example, and embodiments are not limited thereto. For example, a cross-section of the mold 200 may be designed (or formed) in various shapes, as described with reference to FIGS. 7 to 12.

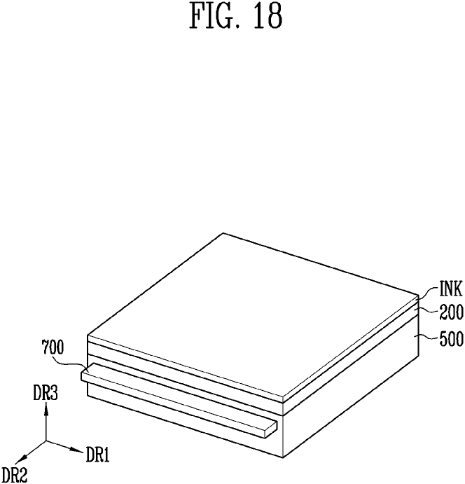

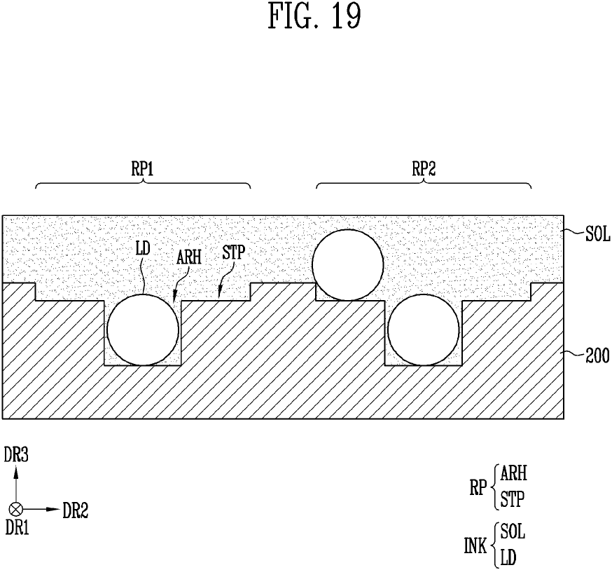

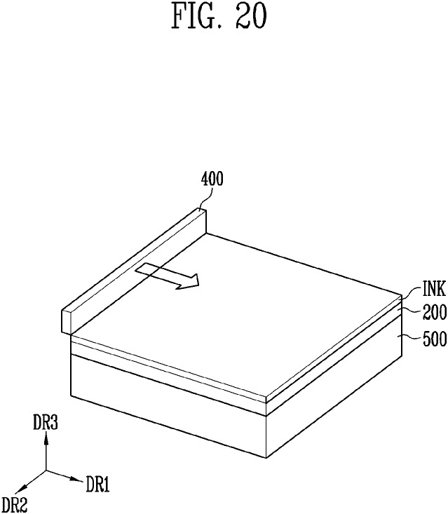

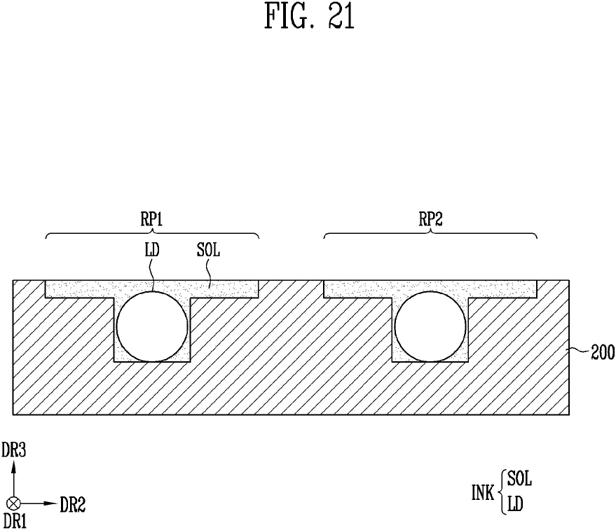

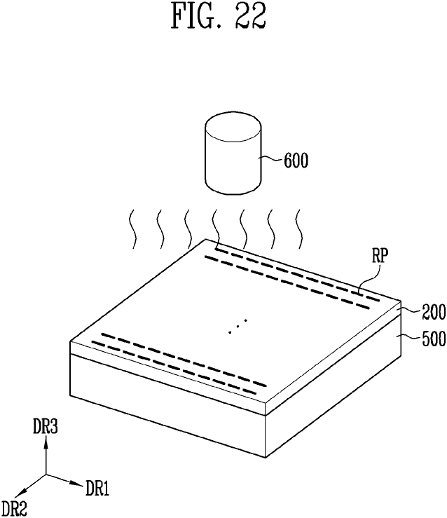

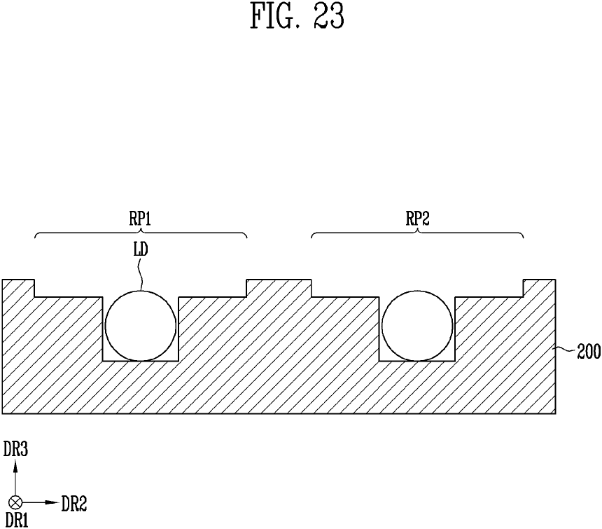

Thereafter, a portion of the ink INK on the mold 200 may be removed. In an embodiment, as shown in FIGS. 18 to 23, the mold 200 may be vibrated by using the first vibrating device 700 to fill the recessed portions RP with at least a portion of the light emitting elements LD (refer to FIGS. 18 and 19), the surface of the mold 200 may be scraped with the doctor blade 400 to align the light emitting elements LD on the mold 200 (refer to FIGS. 20 and 21), and the solvent SOL of the ink INK remaining on the surface of the mold 200 may be removed (refer to FIGS. 22 and 23) by irradiating light to the surface of the mold 200.

As shown in FIGS. 18 and 19, the light emitting elements LD may be filled in the first recessed portion RP1 and the second recessed portion RP2 by vibration of the mold 200 by the first vibrating device 700. For example, the light emitting element LD disposed on the step portion STP may be fallen into the alignment hole ARH. Accordingly, the mold 200 may be vibrated so that the light emitting elements LD are filled in all recessed portions RP. In an embodiment, the first vibrating device 700 may include a sound wave vibrator or an ultrasonic vibrator.

According to an embodiment, as shown in FIG. 19, a portion of the light emitting elements LD may remain on the surface of the mold 200 other than the alignment hole ARH.

In another example, the mold vibration process of FIG. 18 may be omitted.

Thereafter, as shown in FIGS. 20 and 21, the surface of the mold 200 may be scraped with the doctor blade 400, and thus the light emitting elements LD may be aligned in the alignment holes ARH (refer to FIG. 19). The doctor blade 400 may be moved with contacting a portion of the surface of the mold 200 in a direction (for example, the first direction DR1) with a (certain) contact pressure.

The light emitting elements LD disposed in a portion other than the alignment hole ARH may be removed together with the solvent SOL.

Thereafter, in an embodiment, as shown in FIGS. 22 and 23, the solvent SOL (shown in FIG. 21) of the ink INK remaining on the surface of the mold 200 may be removed by light irradiation of the drying device 600. For example, all of the solvent SOL may be evaporated by the drying device 600. Accordingly, only the light emitting elements LD disposed or fixed in the recessed portion RP remain in the mold 200.

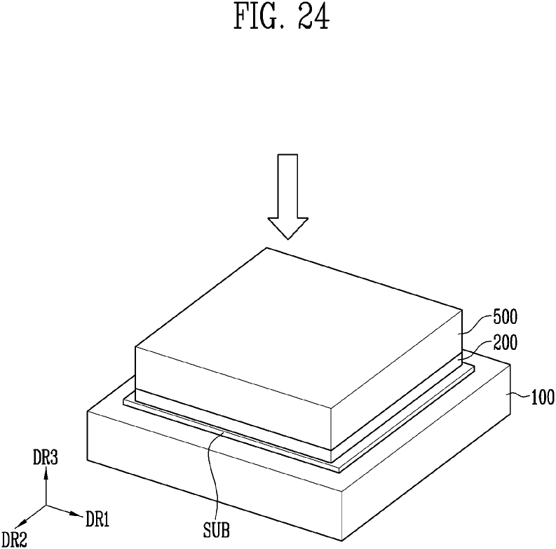

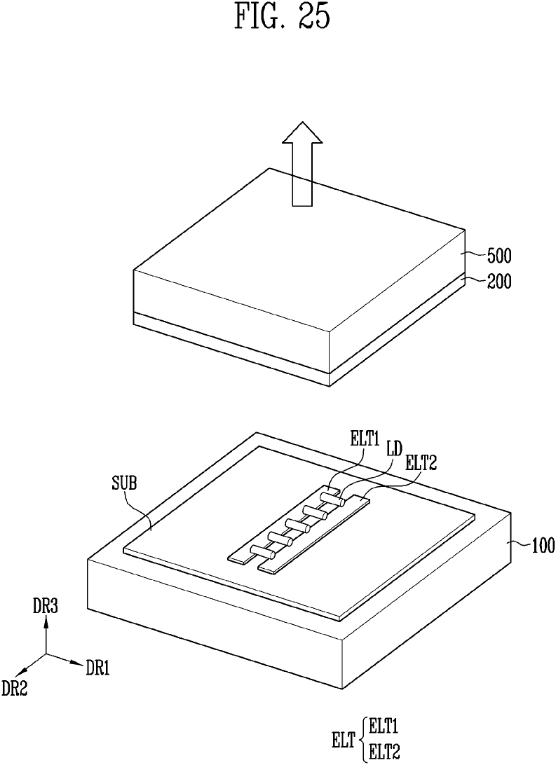

Thereafter, as shown in FIG. 24, the light emitting elements LD may be disposed on the electrodes ELT1 and ELT2 (shown in FIG. 25) formed on the substrate SUB by compressing the mold 200 and the substrate SUB. First, as shown in FIG. 24, the substrate SUB and the stage 100 may be aligned or disposed on the mold 200 in a state, in which the substrate SUB and the stage 100 are turned over. Thus, the recessed portion RP may face the third direction DR3. In a state in which the substrate SUB and the stage 100 are turned over, the mold 200 and the substrate SUB may be compressed. In a state in which the mold 200 and the substrate SUB are bonded together, the stage 100, the substrate SUB, the mold 200, and the pressure applying device 500 may be turned over again. Accordingly, positions of the stage 100, the substrate SUB, the mold 200, and the pressure applying device 500 as shown in FIG. 24 may be created. For example, in a state in which the mold 200 and the pressure applying device 500 are turned over, a (certain) pressure may be applied in a direction opposite to the third direction DR3 through the pressure applying device 500.

Accordingly, the light emitting element LD may be separated from the recessed portion RP and may be disposed on the electrodes ELT1 and ELT2 of the substrate SUB.

Thereafter, as shown in FIG. 25, the mold 200 from which the light emitting elements LD are separated may be separated from the substrate SUB. In an embodiment, the mold 200 may be lifted or moved in the third direction DR3. The light emitting elements LD may be arranged on the first electrode ELT1 and the second electrode ELT2 to correspond to an arrangement of the recessed portions RP of the mold 200.

For example, the light emitting elements LD may be disposed on the first electrode ELT1 and the second electrode ELT2 in an aligned state by the arrangement of the recessed portion RP of the mold 200. Therefore, misalignment of the light emitting elements LD may be minimized and greatly reduced. Accordingly, a product defect may be reduced, and alignment reliability and manufacturing yield may be improved.

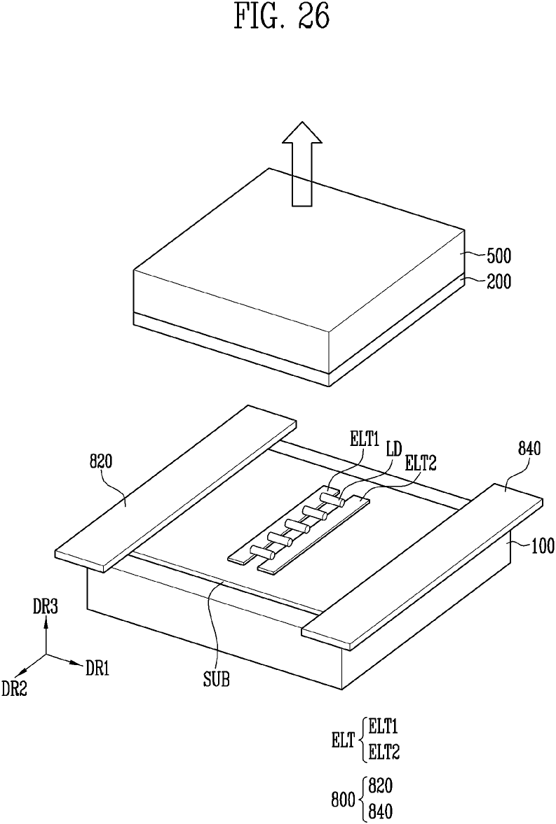

FIG. 26 is a schematic diagram illustrating an example of a process of separating the substrate SUB and the mold 200 of FIG. 25.

Referring to FIG. 26, the mold 200 separated from the light emitting elements LD may be separated from the substrate SUB.

In an embodiment, the light emitting elements LD may be fixed on the first electrode ELT1 and the second electrode ELT2 by applying the electric field on the substrate SUB by the electric field applying device 800. In this state, the mold 200 may be moved in the third direction DR3 to be separated from the substrate SUB.

The light emitting elements LD may receive the dielectrophoretic force by the electric field, and the position/orientation of each of the light emitting elements LD may be fixed on the substrate SUB in case that the electric field is applied. Accordingly, separation, misalignment, and the like of the light emitting element LD that may occur during separation of the mold 200 and the substrate SUB may be prevented or reduced. Therefore, process reliability may be further improved.

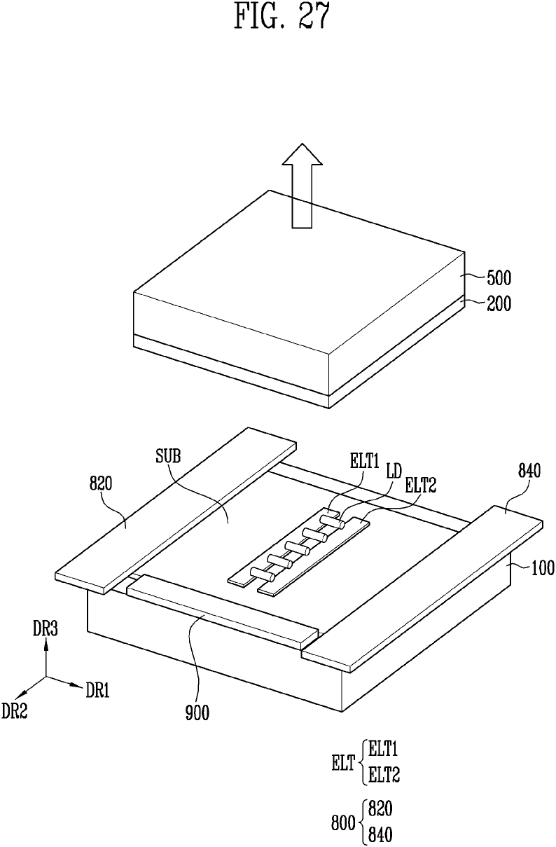

FIG. 27 is a schematic diagram illustrating another example of a process of separating the substrate SUB and the mold 200 of FIG. 25.

Referring to FIG. 27, the mold 200 separated from the light emitting elements LD may be separated from the substrate SUB.

In an embodiment, the light emitting elements LD may be fixed on the first electrode ELT1 and the second electrode ELT2 by applying the electric field on the substrate SUB by the electric field applying device 800, a vibration may be applied to the substrate SUB by the second vibrating device 900, and in this state, the mold 200 may be moved in the third direction DR3 to be separated from the substrate SUB.

The second vibrating device 900 may assist a separation process of the mold 200 and the substrate SUB. The separation of the mold 200 and the substrate SUB and the separation of the mold 200 and the ink INK (for example, the solvent SOL of the ink INK) may be improved by the vibration by the second vibrating device 900. Since an operation by the second vibrating device 900 is described above with reference to FIG. 15, a redundant description is omitted for descriptive convenience.

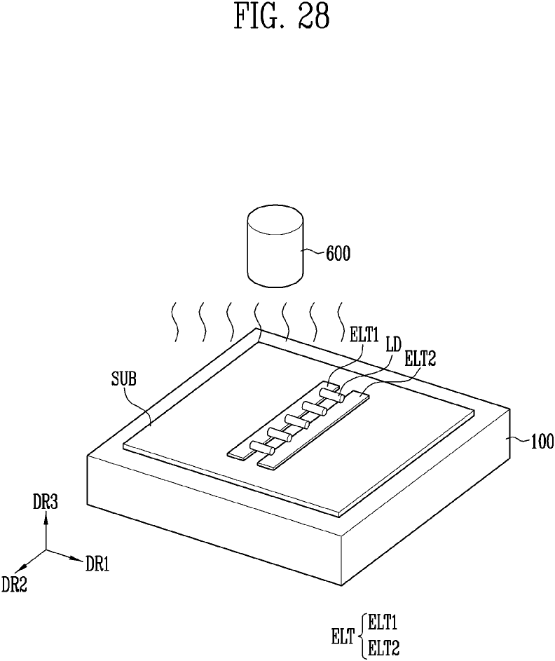

FIG. 28 is a schematic diagram illustrating an example of a process of removing the solvent SOL of the ink INK.

Referring to FIGS. 25 and 28, after the mold 200 is separated from the substrate SUB, the solvent SOL of the ink INK remaining on the surface of the substrate SUB may be completely removed by irradiating light onto the substrate SUB.

In an embodiment, the process of removing the ink INK remaining in the mold 200 described with reference to FIGS. 22 and 23 may be replaced with a process of removing the ink INK remaining on the substrate SUB after the mold 200 and the substrate SUB are separated of FIG. 28.

As described above, the apparatus 1000, 1000A, 1000B, or 1000C for manufacturing the display device DD and the method of manufacturing the display device DD according to embodiments may provide the light emitting elements LD arranged in advance by using the arrangement of the recessed portions RP of the mold 200 on the electrodes ELT1 and ELT2 of the substrate SUB. Therefore, misalignment of the light emitting elements LD may be greatly reduced. Accordingly, a product defect may be reduced, and alignment reliability and manufacturing yield may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display device, the apparatus comprising:
a stage on which a substrate of the display device is disposed;
a mold including a surface including recessed portions;
an injector that applies an ink including light emitting elements on the surface of the mold;
a doctor blade that removes the ink disposed on the surface of the mold and remains the ink disposed in the recessed portions of the mold; and
a compressor that compresses the surface of the mold to the substrate.

2. The apparatus of claim 1, wherein
a depth of each of the recessed portions is greater than a diameter of each of the light emitting elements, and
the depth of each of the recessed portions is smaller than about 1.5 times of the diameter of each of the light emitting elements.

3. The apparatus of claim 2, wherein each of the recessed portions includes an alignment hole filled with at least one of the light emitting elements.

4. The apparatus of claim 3, wherein
a length of the alignment hole in a first direction is greater than a length of each of the light emitting elements,
a width of the alignment hole in a second direction intersecting the first direction is greater than the diameter, and
the width of the alignment hole in the second direction is smaller than about 1.5 times of the diameter.

5. The apparatus of claim 4, wherein
the recessed portions are disposed in the first direction and the second direction, and
the recessed portions are disposed in a shape in which the light emitting elements are aligned on the substrate.

6. The apparatus of claim 5, wherein
the doctor blade scrapes the ink in a direction on the surface of the mold, and
the light emitting elements are disposed in an alignment form of the recessed portions.

7. The apparatus of claim 3, wherein a lower surface of the alignment hole is substantially flat.

8. The apparatus of claim 3, wherein the alignment hole includes a curved surface or an inclined surface.

9. The apparatus of claim 3, wherein each of the recessed portions further includes a step portion or an inclined surface adjacent to the alignment hole.

10. The apparatus of claim 1, further comprising:
a dryer that evaporates and removes a solvent of the ink remaining on the surface of the mold or on a surface of the substrate.

11. The apparatus of claim 10, further comprising:
a vibrator that vibrates the mold to which the ink is applied.

12. The apparatus of claim 11, wherein
the vibrator is configured to vibrate the mold by generating a sound wave or an ultrasonic wave, and
at least one of the light emitting elements is filled in each of the recessed portions by the vibrator.

13. The apparatus of claim 11, wherein in case that the mold and the substrate are separated, the vibrator is configured to vibrate the substrate.

14. The apparatus of claim 10, further comprising:
an electric field generator that fixes a position of each of the light emitting elements by applying an electric field to the substrate in case that the mold and the substrate are separated.

15. A method of manufacturing a display device, the method comprising:
applying an ink including light emitting elements to a surface of a mold including recessed portions;
removing the ink disposed on the surface of the mold and remaining the ink disposed in the recessed portions of the mold by using a doctor blade;
compressing the mold to a substrate of the display device to dispose the light emitting elements on electrodes formed on the substrate; and
separating the mold from which the light emitting elements are separated from the substrate.

16. The method of claim 15, wherein the removing of the ink comprises:
aligning the light emitting elements by scraping the surface of the mold by the doctor blade; and
removing a solvent of the ink remaining on the surface of the mold by irradiating light to the surface of the mold.

17. The method of claim 15, wherein the removing of the ink comprises:
vibrating the mold by using a vibrator so that at least one of the light emitting elements is filled in each of the recessed portions;
aligning the light emitting elements by scraping the surface of the mold by the doctor blade; and
removing a solvent of the ink remaining on the surface of the mold by irradiating light to the surface of the mold.

18. The method of claim 15, wherein the separating of the mold from the substrate comprises:
fixing the light emitting elements on the electrodes by applying an electric field on the substrate by an electric field generator; and
separating the mold from the substrate by moving the mold in a vertical direction.

19. The method of claim 18, wherein the separating of the mold from the substrate further comprises removing a solvent of the ink remaining on a surface of the substrate by irradiating light on the substrate from which the mold is separated.

20. The method of claim 15, wherein the separating of the mold from the substrate comprises:
fixing the light emitting elements on the electrodes by applying an electric field on the substrate by an electric field generator;
applying a vibration to the substrate by a vibrator; and
separating the mold from the substrate by moving the mold in a vertical direction.
